(19) United States
(12) Patent Application Publication
(10) Pub. No.: US 2006/0006768 A1
(43) Pub. Date: Jan. 12, 2006

(54) Piezoelectric resonator and method for fabricating the same

(75) Inventor: Motonori Ishii, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/174,541

(22) Filed: Jul. 6, 2005

(30) Foreign Application Priority Data
Jul. 6, 2004 (JP) 2004-199168
Jul. 1, 2005 (JP) 2005-193623

(51) Int. Cl. H01L 41/04

(52) U.S. Cl. 310/344

(57) ABSTRACT

A piezoelectric resonator includes a resonator film held along the principal surface of a substrate and constituted by a piezoelectric film, a lower electrode and an upper electrode. The lower electrode and the upper electrode are opposed to each other and provided on the lower face and the upper face of the piezoelectric film, respectively. A frame is provided at a peripheral portion of the upper face of the upper electrode. The lower face of a lid is supported by the frame. An upper cavity is formed between the lid and the upper face of the upper electrode.

### CROSS-REFERENCE TO RELATED APPLICATION

This application claims priority under 35 U.S.C. §119 on Patent Application No. 2004-199168 filed in Japan on Jul. 6, 2004, the entire contents of which are hereby incorporated by reference. The entire contents of Patent Application No. 2005-193623 filed in Japan on Jul. 1, 2005 are also incorporated by reference.

### BACKGROUND OF THE INVENTION

The present invention relates to piezoelectric resonators and methods for fabricating the same.

With recent global proliferation of cellular phones, the number of cellular phones in use has been increasing in an accelerated pace. The cellular phones need to process a plurality of RF signals with different frequencies, and it is generally necessary to remove RF signals with frequencies other than a desired frequency. To remove RF signals with unwanted frequencies and pass only RF signals with a desired frequency, components called RF filters are generally used.

To reduce the size of such filters and enhance the performance thereof, the use of piezoelectric resonators using bulk acoustic waves has been contemplated. A piezoelectric resonator has an impedance peak at a resonance frequency determined by the total thickness of a piezoelectric film and electrode films in a portion (hereinafter, referred to as a “cavity portion”) in which an ultrasonic wave is induced in the thickness direction. However, an ultrasonic wave propagating in the lateral direction causes an impedance peak called a spurious component at another frequency near the resonance frequency. Such generation of a spurious component causes degradation of characteristics of the piezoelectric resonator. Accordingly, to enhance the performance of the piezoelectric resonator, it is important to reduce the spurious component.

A main reason for the generation of a spurious component is leakage of vibration energy generated in the cavity portion into an adjacent part of the cavity portion. Therefore, it is important to confine energy in the cavity portion. In Japanese Unexamined Patent Publication (Kokai) No. 2002-43879, for example, the thickness of the piezoelectric film at the cavity portion is larger than that at an adjacent part of the cavity portion, so that vibration energy is more efficiently confined in the cavity portion.

A piezoelectric resonator needs vertical vibration of a cavity portion, and thus the cavity portion should be kept from contact with a substrate and a sealing material. Therefore, in packaging the substrate on which the piezoelectric resonator is formed, resin sealing, which is easily implemented at low cost, cannot be used. This is because in a resin-sealed package, the upper portion of the cavity portion is in contact with the resin and therefore vibration attenuates.

In addition, moisture from outside the piezoelectric resonator causes degradation of the piezoelectric film to degrade the performance of the resonator. Therefore, sealing of the piezoelectric resonator is necessary. In view of this, a hermetically sealed package, for example, is generally used in packaging a piezoelectric resonator and the upper portion of a cavity portion is kept from contact with any material so as to prevent degradation of performance due to entering of moisture from outside. (see, for example, Japanese Unexamined Patent Publication (Kokai) No. 2000-261280).

However, changing the thickness of a piezoelectric film as in the foregoing conventional methods causes a problem in which process steps become complicated and the productivity is largely reduced. In addition, it is difficult to make the thickness of a piezoelectric film at a cavity portion greatly differ from that at its adjacent part, so that there arises a problem in which a spurious component is insufficiently reduced. Furthermore, even if the thickness of the piezoelectric film is changed, it is still necessary to form a structure in which the upper portion of a cavity portion is kept from contact with any material. Accordingly, a material such as ceramic that is much more expensive than a resin, for example, is needed for packaging. Moreover, the process for packaging is complicated, thus causing a problem in which the yield decreases in mass production of piezoelectric resonators.

### SUMMARY OF THE INVENTION

It is therefore an object of the present invention to provide a piezoelectric resonator in which spurious components are effectively reduced and which does not need a hermetically sealed package.

In order to achieve this object, a piezoelectric resonator according to the present invention includes a lid supported above an upper electrode.

Specifically, a first piezoelectric resonator according to the present invention includes: a resonator film held along a principal surface of a substrate and constituted by a piezoelectric film, a lower electrode and an upper electrode, the lower electrode and the upper electrode being opposed to each other and provided on the lower face and the upper face of the piezoelectric film, respectively; and a frame provided at a peripheral portion of the upper face of the upper electrode; and a lid having a lower face supported by the frame, wherein an upper cavity is formed between the lid and the upper face of the upper electrode.

In the first piezoelectric resonator, the thickness of a portion adjacent to a cavity portion of the piezoelectric film where a vertical acoustic wave is confined is much larger than that of the cavity portion, so that the resonance frequency in the cavity portion much differs from that in the other portion. Accordingly, spurious components occurring in the piezoelectric resonator are reduced. Accordingly, even when a resin film, for example, is formed on the lid, vibration of the cavity portion does not attenuate. Accordingly, the piezoelectric resonator can be sealed with a resin package.

In the first piezoelectric resonator, the upper cavity is preferably sealed. With this structure, in resin packaging, the resin does not flow into the cavity, thus ensuring the resin packaging. In addition, deterioration of the upper electrode caused by moisture or the like in an atmosphere is prevented.

In the first piezoelectric resonator, a lower cavity is preferably formed between a lower face of the lower electrode and the substrate. In this case, the first piezoelectric resonator preferably further includes a lower-electrode supporter provided between the substrate and the lower electrode and supporting a peripheral portion of the lower face of the lower electrode. With this configuration, formation of the lower cavity is ensured and, in addition, the resonance frequency in the cavity portion is made differ from that in the other portion.

A second piezoelectric resonator according to the present invention includes: a plurality of resonator films held along a principal surface of a substrate, each of the resonator films being constituted by a piezoelectric film, a lower electrode and an upper electrode, the lower electrode and the upper electrode being opposed to each other and provided on the lower face and the upper face of the piezoelectric film, respectively; a plurality of frames provided at respective peripheral portions of the upper faces of the upper electrodes; and a lid having a lower face supported by the frames, wherein upper cavities are formed between the lid and the respective upper faces of the upper electrodes.

In the second piezoelectric resonator, the thickness of a portion adjacent to a cavity portion of the piezoelectric film where a vertical acoustic wave is confined is much larger than that of the cavity portion, so that the resonance frequency in the cavity portion much differs from that in the other portion. Accordingly, spurious components occurring in the piezoelectric resonator are reduced. In addition, one lid is held by the plurality of frames, so that the lid is easily formed and the strength thereof is high. Moreover, since a plurality of resonator parts are provided, so that an RF filter, for example, is easily formed.

In the second piezoelectric resonator, at least one of the lower electrode and the upper electrode of at least one of the resonator films preferably has a thickness different from that in the other resonator film(s). With this configuration, piezoelectric resonators having different resonance frequencies are formed on the substrate, thus enabling easy formation of an RF filter, for example.

In the second piezoelectric resonator, the piezoelectric film is preferably common to the resonator films. With this configuration, the plurality of resonator films are easily formed.

A method for fabricating a piezoelectric resonator according to the present invention includes the steps of: (a) preparing a resonator film including a piezoelectric film, a lower electrode and an upper electrode such that the resonator film is held along the principal surface of a first substrate, the lower electrode and the upper electrode being opposed to each other and provided on the lower face and the upper face of the piezoelectric film, respectively; (b) forming a frame on a lid at a position associated with a peripheral portion of the upper face of the upper electrode; and (c) bonding the frame to the peripheral portion of the upper face of the upper electrode so that the lid is supported by the frame, thereby forming an upper cavity between the lid and the upper face of the upper electrode.

With this method, the thickness of a portion adjacent to a cavity portion of the piezoelectric film where a vertical acoustic wave is confined is much larger than that of the cavity portion. Accordingly, a piezoelectric resonator with reduced spurious components is easily implemented. In addition, it is possible to package the piezoelectric resonator with a resin.

Preferably, the method further includes the step of forming a lid-contact film on the peripheral portion of the upper face of the upper electrode between the steps (a) and (c), wherein in the step (c), the frame is bonded to the upper face of the upper electrode with the lid-contact film interposed therebetween. With this method, formation of the lid is ensured.

In the step (c), the upper electrode and the frame are preferably bonded together by heating the upper electrode and the frame with pressure applied thereto. In the step (c), the upper electrode and the frame may be bonded together by eutectic reaction.

The step (a) preferably includes the steps of: forming the piezoelectric film on a second substrate, and then forming the lower electrode on the piezoelectric film; forming a lower-electrode supporter on the first substrate at a position associated with a peripheral portion of the lower electrode; bonding the lower-electrode supporter formed on the first substrate and the lower electrode formed on the second substrate together, thereby forming a lower cavity between the lower electrode and the first substrate; and removing the second substrate such that the face of the piezoelectric film opposite to the face thereof on which the lower electrode is formed is exposed, and then forming the upper electrode on the exposed face.

The step (b) preferably includes the step of etching the lid using the frame as a mask after forming the frame on the lid.

In a piezoelectric resonator and with a method for fabricating the piezoelectric resonator according to the present invention, spurious components are effectively reduced and a hermetically sealed package is unnecessary.

### BRIEF DESCRIPTION OF THE DRAWINGS

FIGS. 1A and 1B illustrate a piezoelectric resonator according to an embodiment of the present invention. FIG. 1A is a plan view and FIG. 1B is a cross-sectional view.

FIG. 2 is a graph showing a calculation result on a spurious characteristic of the piezoelectric resonator according to the embodiment of the present invention.

FIG. 3 is a graph showing a calculation result on a spurious characteristic of a piezoelectric resonator according to a comparative example.

FIGS. 4A through 4D are cross-sectional views illustrating respective process steps of fabricating a piezoelectric resonator according to the embodiment of the present invention in the order of fabrication.

FIGS. 5A and 5B are cross-sectional views illustrating respective process steps of fabricating a piezoelectric resonator according to the embodiment of the present invention in the order of fabrication.

FIGS. 6A and 6B are cross-sectional views illustrating respective process steps of fabricating a piezoelectric resonator according to another example of the embodiment of the present invention in the order of fabrication.

FIGS. 7A and 7B are cross-sectional views illustrating respective process steps of fabricating a piezoelectric resonator according to still another example of the embodiment of the present invention in the order of fabrication.

FIG. 8 is a cross-sectional view illustrating a piezoelectric resonator according to a modified example of the embodiment of the present invention.

### DETAILED DESCRIPTION OF THE INVENTION

### Embodiment

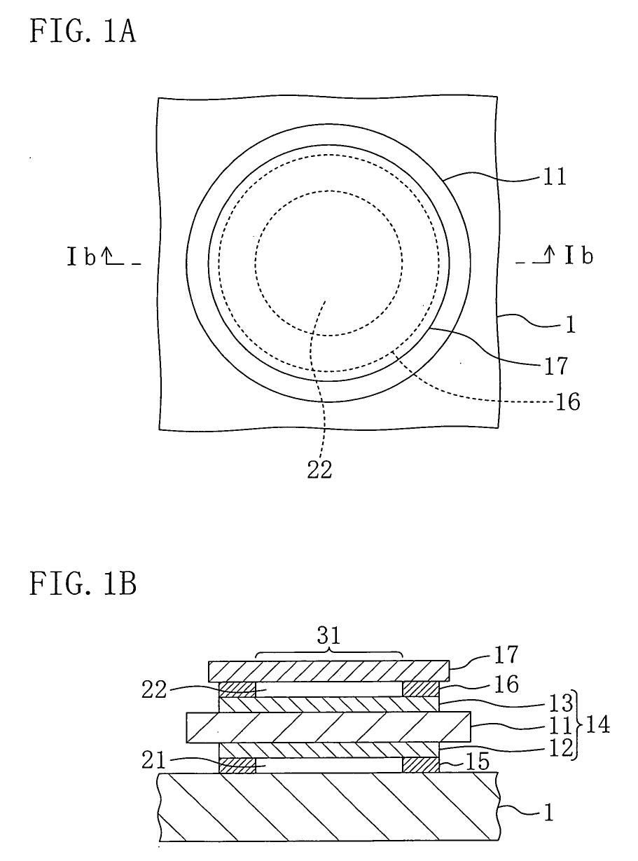

A piezoelectric resonator and a method for fabricating the resonator according to an embodiment of the present invention will be described with reference to the drawings. FIGS. 1A and 1B illustrate a piezoelectric resonator according to this embodiment. FIG. 1A is a plan view and FIG. 1B is a cross-sectional view taken along the line 1b-1b in FIG. 1A. As shown in FIG. 1B, a resonator film 14 constituted by a piezoelectric film 11 and a pair of opposed lower and upper electrodes 12 and 13 provided on the lower and upper faces of the piezoelectric film 11, respectively, is supported above the principal surface of a supporting substrate 1.

The resonator film 14 is supported above the supporting substrate 1 with a lower-electrode supporter 15, which is in contact with a peripheral portion of the lower electrode 12, interposed therebetween. In this manner, a lower cavity 21 is formed between the lower electrode 12 and the supporting substrate 1. A portion of the resonator film 14 under which the lower cavity 21 is formed is a cavity portion 31 vibrating in the thickness direction.

A lid 17 and a frame 16 that is bonded to a peripheral portion of the upper face of the upper electrode 13 and supports the lid 17 from beneath the lid 17 are provided on the upper electrode 13 so that an upper cavity 22 is formed between the lid 17 and the upper electrode 13. Accordingly, even when the surface of the lid 17 is covered with a resin film, vibration induced in the cavity portion 31 does not attenuate. This enables sealing of a piezoelectric resonator with a resin for packaging.

FIG. 1 illustrates only one piezoelectric resonator. However, a plurality of piezoelectric resonators may be formed on the supporting substrate 1. In the case where a plurality of piezoelectric resonators are formed on the supporting substrate 1, one lid 17 may be used in common for these piezoelectric resonators.

The resonance frequency of the piezoelectric resonator is determined by the total thickness of the vibrating portion, i.e., the cavity portion 31 constituted by the piezoelectric film 11, the lower electrode 12 and the upper electrode 13. However, vibration also occurs in portions other than the cavity portion 31, so that this vibration might cause a spurious component.

In particular, if the difference in thickness between the cavity portion 31 and the other portion is small, the portion other than the cavity portion 31 vibrates at a frequency substantially equal to that in the cavity portion 31, so that the spurious component increases. In addition, vibration energy in the cavity portion 31 is likely to leak into the adjacent portion, so that the efficiency in energy confinement in the cavity portion 31 decreases.

On the other hand, in the piezoelectric resonator of this embodiment, the lower-electrode supporter 15, the frame 16 and the lid 17 are additionally formed on the lower and upper faces of the piezoelectric film 11 in the portion other than the cavity portion 31. Accordingly, the thickness of the cavity portion 31 greatly differs from that of the other portion, so that a spurious component generated in the piezoelectric resonator is reduced.

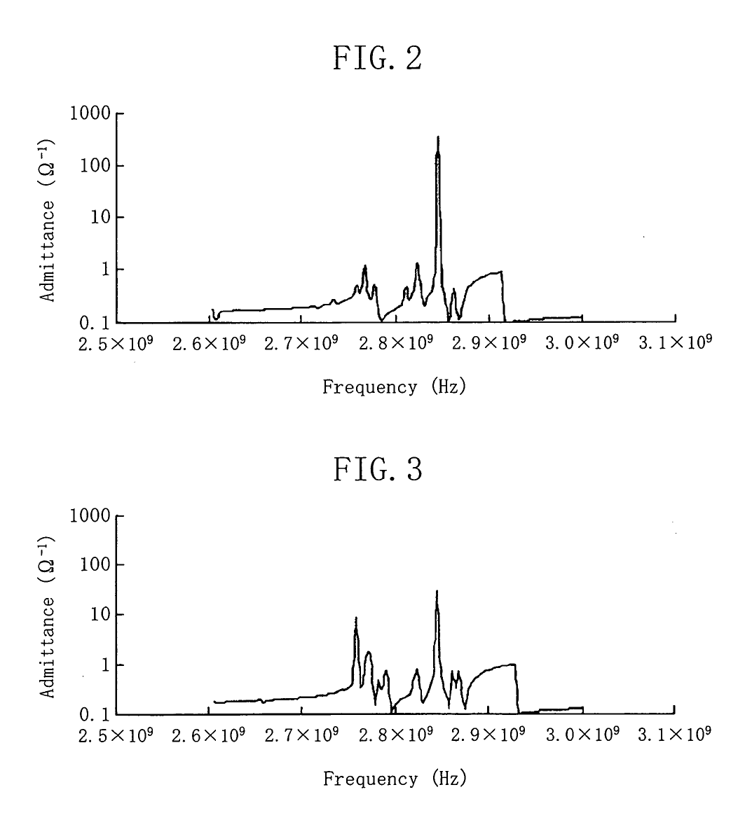

FIGS. 2 and 3 show calculation results on spurious modes caused in respective piezoelectric resonators. In FIGS. 2 and 3, the abscissa indicates the frequency and the ordinate indicates the admittance between an upper electrode and a lower electrode.

FIG. 2 shows a calculation result in the piezoelectric resonator of this embodiment. The substrate 1 is a silicon substrate with a thickness of 450 μm. The piezoelectric film 11 has a thickness of 0.5 μm and is made of aluminum nitride. Each of the lower electrode 12 and the upper electrode 13 has a thickness of 0.2 μm and a width of 200 μm and is made of tungsten. Each of the lower-electrode supporter 15 and the frame 16 has a thickness of 2 μm and a width of 40 μm and is made of gold. The lid 17 has a thickness of 50 μm and is made of silicon.

As shown in FIG. 2, only one high peak of the resonance frequency is present at about 2.85 GHz in the piezoelectric resonator. Peaks caused by spurious components are very low, as compared to the peak of the resonance frequency. FIG. 3 shows a calculation result in a resonator similar to the piezoelectric resonator of this embodiment but different in that the lid 17 and the frame 16 are omitted. In this case, the peak of the resonance frequency at about 2.85 GHz is low and the peaks caused by spurious components are high, as compared to the resonator of this embodiment.

From these results, it is clear that the piezoelectric resonator of this embodiment has the effect of reducing spurious components.

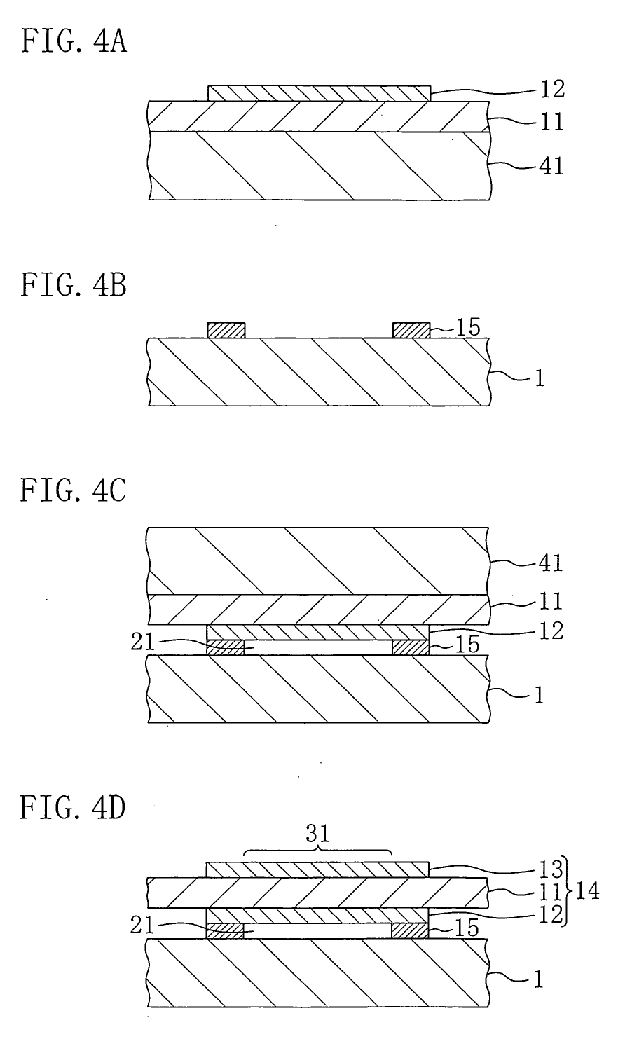

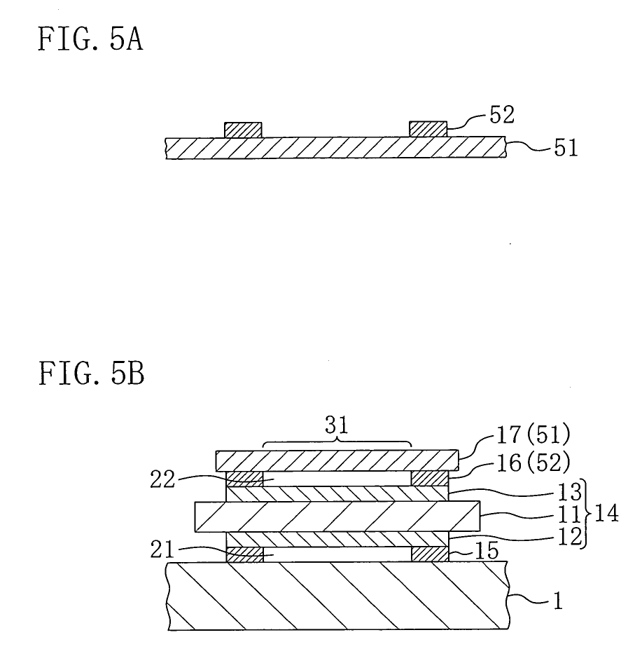

Now, a method for fabricating a piezoelectric resonator according to this embodiment will be described with reference to the drawings. FIGS. 4A through 4D and FIGS. 5A and 5B illustrate respective process steps of a method for fabricating a piezoelectric resonator according to this embodiment in the order of fabrication. First, as shown in FIG. 4A, a piezoelectric film 11 made of aluminum nitride is formed on a temporary substrate 41 made of sapphire. Then, a lower electrode 12 made of tungsten is formed on the piezoelectric film 11.

Next, as shown in FIG. 4B, a lower-electrode supporter 15 made of gold is formed on a supporting substrate 1. The lower-electrode supporter 15 is formed at a position corresponding to a peripheral portion of the lower electrode 12 when the supporting substrate 1 and the temporary substrate 41 are placed face-to-face.

Then, as shown in FIG. 4C, the supporting substrate 1 and the temporary substrate 41 are placed face-to-face such that the lower-electrode supporter 15 and the lower electrode 12 are in close contact with each other in an appropriate position and then heated with pressure applied thereto, so that the lower-electrode supporter 15 and the lower electrode 12 are bonded together.

Thereafter, as shown in FIG. 4D, the temporary substrate 41 is removed, and then an upper electrode 13 made of tungsten is formed on the exposed upper face of the piezoelectric film 11. It is sufficient that the temporary substrate 41 is removed by a known method such as laser lift-off or polishing. To remove the temporary substrate 41 by polishing, silicon carbide (SiC) may be used for the temporary substrate 41.

Then, as shown in FIG. 5A, a frame-prototype film 52 made of gold is formed on a lid-prototype film 51 made of silicon. The frame-prototype film 52 is formed by using, for example, a method including vapor deposition and lift-off at a position corresponding to a peripheral portion of the upper electrode 13 when the supporting substrate 1 and the lid-prototype film 51 are placed face-to-face.

Subsequently, as shown in FIG. 5B, the supporting substrate 1 and the lid-prototype film 51 are placed face-to-face such that the frame-prototype film 52 and the peripheral portion of the upper electrode 13 are in close contact with each other in an appropriate position, and then heated with pressure applied thereto. In this manner, a frame 16 bonded to the peripheral portion of the upper face of the upper electrode 13 and a lid 17 whose lower face is partly supported by the frame 16 are formed.

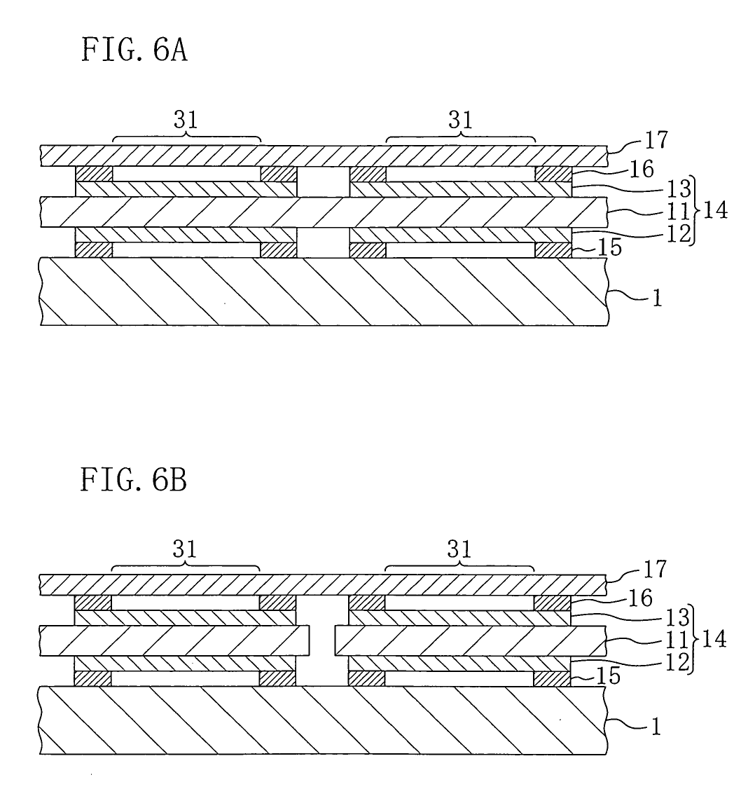

A plurality of piezoelectric resonators may be formed on the supporting substrate 1. In such a case, one lid 17 may be used in common for these piezoelectric resonators as shown in FIG. 6A. In this manner, the lid 17 is bonded to all the piezoelectric resonators by one bonding process. An unnecessary portion of the piezoelectric film 11 may be cut off as shown in FIG. 6B. This structure reduces spurious components even when the distance between adjacent piezoelectric resonators is small. The lid 17 may be divided into pieces associated with the respective piezoelectric resonators.

A plurality of piezoelectric resonators having different resonance frequencies implemented by making the thickness of the upper electrode 13 or the lower electrode 12 differ from one resonator to another may be formed on the substrate. This enables an RF filter to be formed with ease.

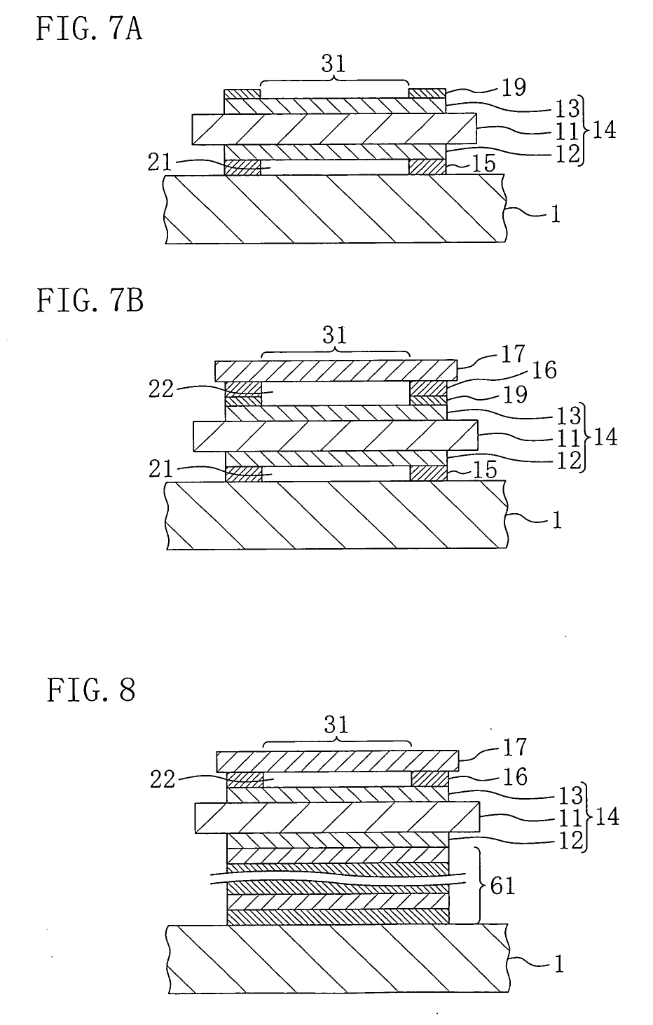

In the method for fabricating a piezoelectric resonator according to this embodiment, the frame 16 and the upper electrode 13 are bonded by thermocompression bonding, as an example. Alternatively, a gold-tin alloy, for example, may be used for the frame 16 and the upper electrode 13 so that the frame 16 and the upper electrode 13 are bonded together by eutectic reaction. In such a case, it is possible to reduce the processing temperature during the bonding. In addition, the frame 16 and the upper electrode 13 are directly bonded in the example. Alternatively, a frame bonding layer 19 may be formed on the upper electrode 13 beforehand as shown in FIG. 7 so that the frame 16 and the upper electrode 13 are bonded together with the frame bonding layer 19 interposed therebetween.

The surface of the lid-prototype film 51 may be etched to a depth of several μm with the frame-prototype film 52 used as a mask after formation of the frame-prototype film 52 on the lid-prototype film 51. Then, even when a thin frame-prototype film 52 is formed by, for example, vapor deposition, the space between the lid 17 and the upper electrode 13 is secured, so that formation of the upper cavity 22 can be ensured.

In this embodiment, each piezoelectric resonator has a planar circular shape. With this shape, modes other than a given acoustic-wave mode are less likely to be generated, so that spurious components are further reduced. The piezoelectric resonator may also have a planar rectangular or square shape in consideration of formability of the piezoelectric film 11. In such a case, spurious components are also reduced as long as the cavity portion 31 has a planar circular shape. The planar shape of each of the piezoelectric resonator and the cavity portion may be a shape that does not have parallel sides such as a pentagon.

In this embodiment, the lower cavity 21 is formed by bonding the piezoelectric film 11 on which the lower electrode 12 is formed to the supporting substrate 1 on which the lower-electrode supporter 15 is formed. Alternatively, the lower cavity 21 may be formed by bonding the piezoelectric film 11 onto a supporting substrate 1 having a recess. Instead of bonding, a sacrificial layer may be used.

### Modified Example of Embodiment

Hereinafter, a piezoelectric resonator according to a modified example of the embodiment will be described with reference to the drawings. FIG. 8 illustrates a cross-sectional structure of the piezoelectric resonator of this modified example. In FIG. 8, components already shown in FIG. 1 are denoted by the same reference numerals, and description thereof will be omitted.

As shown in FIG. 8, in the piezoelectric resonator of this modified example, an acoustic multilayer film 61 is formed under a lower electrode 12. This structure also reduces spurious components in the piezoelectric resonator and enables easy packaging.

According to the present invention, a piezoelectric resonator in which spurious components are effectively reduced and for which a hermetically sealed package is unnecessary is achieved. Therefore, the present invention is useful for piezoelectric resonators and methods for fabricating the piezoelectric resonators.

What is claimed is:

1. A piezoelectric resonator, comprising:
a resonator film held along a principal surface of a substrate and constituted by a piezoelectric film, a lower electrode and an upper electrode, the lower electrode and the upper electrode being opposed to each other and provided on the lower face and the upper face of the piezoelectric film, respectively; and
a frame provided at a peripheral portion of the upper face of the upper electrode; and
a lid having a lower face supported by the frame,
wherein an upper cavity is formed between the lid and the upper face of the upper electrode.

2. The piezoelectric resonator of claim 1, wherein the upper cavity is sealed.

3. The piezoelectric resonator of claim 1, wherein a lower cavity is formed between a lower face of the lower electrode and the substrate.

4. The piezoelectric resonator of claim 3, further comprising a lower-electrode supporter provided between the substrate and the lower electrode and supporting a peripheral portion of the lower face of the lower electrode.

5. A piezoelectric resonator, comprising:
a plurality of resonator films held along a principal surface of a substrate, each of the resonator films being constituted by a piezoelectric film, a lower electrode and a upper electrode, the lower electrode and the upper electrode being opposed to each other and provided on the lower face and the upper face of the piezoelectric film, respectively;
a plurality of frames provided at respective peripheral portions of the upper faces of the upper electrodes; and
a lid having a lower face supported by the frames,
wherein upper cavities are formed between the lid and the respective upper faces of the upper electrodes.

6. The piezoelectric resonator of claim 5, wherein at least one of the lower electrode and the upper electrode of at least one of the resonator films has a thickness different from that in the other resonator film(s).

7. The piezoelectric resonator of claim 5, wherein the piezoelectric film is common to the resonator films.

8. A method for fabricating a piezoelectric resonator, the method comprising the steps of:
(a) preparing a resonator film including a piezoelectric film, a lower electrode and an upper electrode such that the resonator film is held along the principal surface of a first substrate, the lower electrode and the upper electrode being opposed to each other and provided on the lower face and the upper face of the piezoelectric film, respectively;
(b) forming a frame on a lid at a position associated with a peripheral portion of the upper face of the upper electrode; and
(c) bonding the frame to the peripheral portion of the upper face of the upper electrode so that the lid is supported by the frame, thereby forming an upper cavity between the lid and the upper face of the upper electrode.

9. The method of claim 8, further comprising the step of forming a lid-contact film on the peripheral portion of the upper face of the upper electrode between the steps (a) and (c),
wherein in the step (c), the frame is bonded to the upper face of the upper electrode with the lid-contact film interposed therebetween.

10. The method of claim 8, wherein in the step (c), the upper electrode and the frame are bonded together by heating the upper electrode and the frame with pressure applied thereto.

11. The method of claim 8, wherein in the step (c), the upper electrode and the frame are bonded together by eutectic reaction.

12. The method of one of claim 8, wherein the step (a) includes the steps of:
forming the piezoelectric film on a second substrate, and then forming the lower electrode on the piezoelectric film;
forming a lower-electrode supporter on the first substrate at a position associated with a peripheral portion of the lower electrode;
bonding the lower-electrode supporter and the lower electrode together, thereby forming a lower cavity between the lower electrode and the first substrate; and
removing the second substrate such that the face of the piezoelectric film opposite to the face thereof on which the lower electrode is formed is exposed, and then forming the upper electrode on the exposed face.

13. The method of claim 8, wherein the step (b) includes the step of etching the lid using the frame as a mask after forming the frame on the lid.
